(19) United States
(12) Patent Application Publication
(10) Pub. No.: US 2010/0307551 A1
(43) Pub. Date: Dec. 9, 2010

(54) FABRICATION OF HIGH-TEMPERATURE THERMOELECTRIC COUPLE

(75) Inventors: Vilupanur A. Ravi, Claremont, CA (US); Billy Chun-Yip Li, Walnut, CA (US); Jean-Pierre Fleurial, Altadena, CA (US); Kurt Star, Chatsworth, CA (US)

Correspondence Address: TOPE-MCKAY & ASSOCIATES;CARY TOPE-MCKAY, 30765 Pacific Coast Highway #420, Malibu, CA, 90265, US

(73) Assignee: California Institute of Technology, Pasadena, CA (US)

(21) Appl. No.: 12/789,198

(22) Filed: May 27, 2010

Related U.S. Application Data
(60) Provisional application No. 61/184,252, filed on Jun. 4, 2009.

(51) Int. Cl. H01L 35/12; B29C 65/00; H01L 35/34

(52) U.S. Cl. 136/236.1; 156/60; 136/201

(57) ABSTRACT

The present invention relates to a high-temperature thermoelectric couple and the method for making the same. The method requires a very small number of fabrication steps. It includes an act of fabricating an n-type leg that, in a stacked configuration, includes a low electrical contact resistance metallization foil that is connected to each of the two sides of Lanthanum Telluride via a thin metallic adhesion layer. Additionally, a p-type leg is fabricated that, in a stacked configuration, includes a low electrical contact resistance metallization foil that is connected to each of the two sides of 14-1-11 Zintl. Finally, CTE-matched, low electrical and thermal resistance plate interconnects are used for each of the two legs to interface with the heat source and heat sink and form an electrical connection.

### PRIORITY CLAIM

The present application is a non-provisional patent application, claiming the benefit of priority of U.S. Provisional Application No. 61/184,252, filed on Jun. 04, 2009, entitled, “Fabrication of Lanthanum Telluride-14-1-11 Zintl High Temperature Thermoelectric Couple.”

### GOVERNMENT RIGHTS

The invention described herein was made in the performance of work under a NASA contract, and is subject to the provisions of Public Law 96-517 (35 USC 202) in which the Contractor has elected to retain title.

### FIELD OF INVENTION

The present invention relates to a thermoelectric couple and, more particularly, to a method for fabricating a Lanthanum Telluride-14-1-11 Zintl High-Temperature Thermoelectric Couple.

### BACKGROUND OF INVENTION

There are several applications in which thermoelectric couples are used at high temperatures. The fabrication of advanced high temperature thermoelectric couples requires the joining of several dissimilar materials, typically including a number of diffusion bonding and brazing steps, to achieve a device capable of operating at elevated temperatures across a large temperature differential (for example, 900 Kelvin). A thermoelectric couple typically comprises a heat collector/exchanger, metallic interconnects on both hot and cold sides, n-type and p-type conductivity thermoelectric elements, and cold side hardware to connect to the cold side heat rejection and provide electrical connections.

Differences in the physical, mechanical and chemical properties of the materials that make up the thermoelectric couple, especially differences in the coefficients of thermal expansion (CTE), result in undesirable interfacial stresses that can lead to mechanical failure of the device. The problem is further complicated by the fact that the thermoelectric materials under consideration have large CTE values, are brittle, and cracks can propagate through them with minimal resistance. Therefore, fabrication of devices utilizing these materials requires the development of innovative processes.

Additionally, the development of more efficient thermoelectric couple technology capable of operating with high-grade heat sources (for example, 1,275 Kelvin) is key to improving the performance of radioisotope thermoelectric generators that support some of the National Aeronautics and Space Administration's (NASA) deep space exploration science missions. In addition, there has been increased interest in the potential of thermoelectric technology to recover waste heat from large scale energy intensive industrial processes and machinery.

Thus, a continuing need exists for a thermoelectric couple that is capable of operating with high-grade heat sources.

### SUMMARY OF INVENTION

While considering the failure of others to make use of all of the above components in this technology space, the inventors realized that a Lanthanum Telluride-14-1-11 Zintl High Temperature Thermoelectric Couple would provide a conversion efficiency of about 10.5 percent, which is about 35 percent better than the thermoelectric coupling technology of the prior art and also could be accomplished fairly simply by benefiting from the similar mechanical properties of both materials (CTE in particular) and matching it with widely available high CTE, highly conductive materials. Thus, the present invention is directed to a method for fabricating such a thermoelectric couple.

The method includes an act of fabricating an n-type leg that, in a stacked configuration, includes a refractory metal foil (e.g., molybdenum foil) that is connected to each of the two sides of Lanthanum Telluride via an adhesion layer (e.g., titanium foil). A p-type leg is fabricated such that in a stacked configuration it includes a refractory metal foil (e.g., molybdenum foil) that is connected to each of the two sides of 14-1-11 Zintl. Further, a thick metal plate (e.g., Nickel) serves as an interconnect between the two legs on the hot side. Finally, separate thick metal plates (e.g., Nickel) are connected to each of the cold ends of the legs for connection with an external device on the cold side.

As can be appreciated by one skilled in the art, the present invention also comprises a thermoelectric couple that is formed according to the fabrication method described herein. Further, the thermoelectric couple is not limited to the particular fabrication method as it can be conceived by any suitable method that results in the end stacked configuration as illustrated and described.

### BRIEF DESCRIPTION OF THE DRAWINGS

The objects, features and advantages of the present invention will be apparent from the following detailed descriptions of the various aspects of the invention in conjunction with reference to the following drawings, where:

FIG. 1 is an illustration of an n-type leg according to the present invention;

FIG. 2 is an illustration of a p-type leg according to the present invention;

FIG. 3 is an illustration of a thermoelectric couple according to the present invention; and

FIG. 4 is an illustration of the thermoelectric couple according to the present invention.

### DETAILED DESCRIPTION

The present invention relates to a thermoelectric couple and, more particularly, to a method for fabricating a Lanthanum Telluride (La₃₋ₓ Te₄)-14-1-11 Zintl High-Temperature Thermoelectric Couple. The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

Before describing the invention in detail, an introduction provides the reader with a general understanding of the present invention. Next, details of the present invention are provided to give an understanding of the specific aspects.

(1) Introduction

As noted above, the development of more efficient thermoelectric couple technology capable of operating with high-grade heat sources (for example, up to 1,275 Kelvin) is key to improving the performance of a variety of technologies.

The solution to the fabrication challenges described above was to develop a highly streamlined process that minimized the number of fabrication steps and thermal cycles, including:
a. Using the appropriate hot shoe material and metal interconnects that possess high electrical and thermal conductivity and that are coefficient of thermal expansion (CTE) matched to the La₃₋ₓ Te₄, and Zintl materials;
b. Using appropriate transition materials to bond the thermoelectric material(s) to the hot shoe material; and
c. Using diffusion bonds capable of long term stability and compatible with both the lanthanum telluride and the Zintl materials.

Lanthanum telluride, based on La₃₋ₓ Te₄ and 14-1-11 Zintls, based on Yb₁₄Mn₁Sb₁₁, have been identified as materials that fulfill this need. The calculated conversion efficiency of such an advanced couple would be about 10.5 percent, about 35 percent better than heritage radioisotope thermoelectric technology that relies on Si-Ge alloys. In addition, unlike Si-Ge alloys, these materials have favorable thermoelectric and mechanical properties allowing them to be combined with many other thermoelectric materials optimized for operation at lower temperatures to achieve conversion efficiency in excess of 15 percent (a factor of 2 increase over the prior art).

(2) Specific Details of the Invention

The inherent challenge of bonding brittle, high-thermal-expansion thermoelectric materials to a hot shoe material that is thick enough to carry the requisite electrical current was overcome by the present invention. A critical advantage over prior art is that the present invention was constructed using all diffusion bonds and a minimum number of assembly steps. Generally speaking, the method includes fabricating an n-type leg, fabricating a p-type leg, and bonding a metal interconnect to each of the legs. The particular fabrication process and the materials used are described in further detail below.

(2.1) Fabricating the N-Type Leg

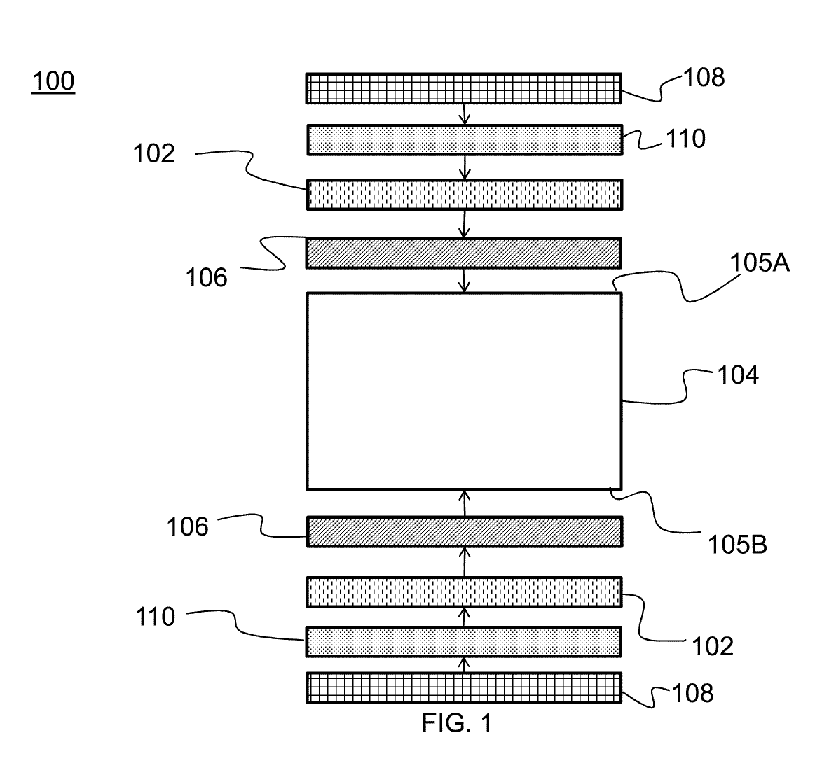

As shown in FIG. 1, to fabricate the n-type leg 100 of the advanced thermoelectric couple, a thin refractory metal foil 102 is applied to both sides of lanthanum telluride 104 (i.e., La₃₋ₓ Te₄). In doing so, the pre-synthesized lanthanum telluride coupon 104 includes at least two sides (a first side 105A and a second side 105B), each of which are bonded to a refractory foil 102 using any suitable bonding technique, a non-limiting example of which includes being diffusion bonded (through hot pressing) to the refractory metal foil 102 using a thin adhesion layer 106. Thus, the lanthanum telluride 104 straddled by an adhesion layer 106 and refractory metal foil 102 results in a stacked configuration that operates as the n-type leg 100.

It should be understood that the refractory metal foil 102 is formed of any suitably refractive material which leads to low electrical contact resistance, a non-limiting example of which includes a Molybdenum foil. Further, any suitable material can be used as the adhesion layer 106, a non-limiting example of which includes a Titanium foil.

As can be appreciated by one skilled in the art, release layers 108 during couple fabrication can be used to act as a barrier between the thermocouple and the hot press. In other words, when using a hot press, the components may have a tendency to stick to the hot press. Thus, the release layers 108 can be employed to allow a user to remove the components from the hot press without the assembly sticking to the hot press. Any suitable material can be used as a release layer 108, a non-limiting example of which includes Grafoil; however, straight Grafoil can create fabrication problems. Thus, a hard substrate layer 110 can be used to solve problems as presented by straight Grafoil. In this aspect, the hard substrate layer 110 is positioned between the release layer 108 and the rest of the assembly. Any suitable material can be used as a hard substrate layer 110, a non-limiting example of which includes Sapphire. It was found that Sapphire solves problems as presented by straight Grafoil and is operable as a desired hard substrate layer 110.

(2.2) Fabricating the P-Type Leg

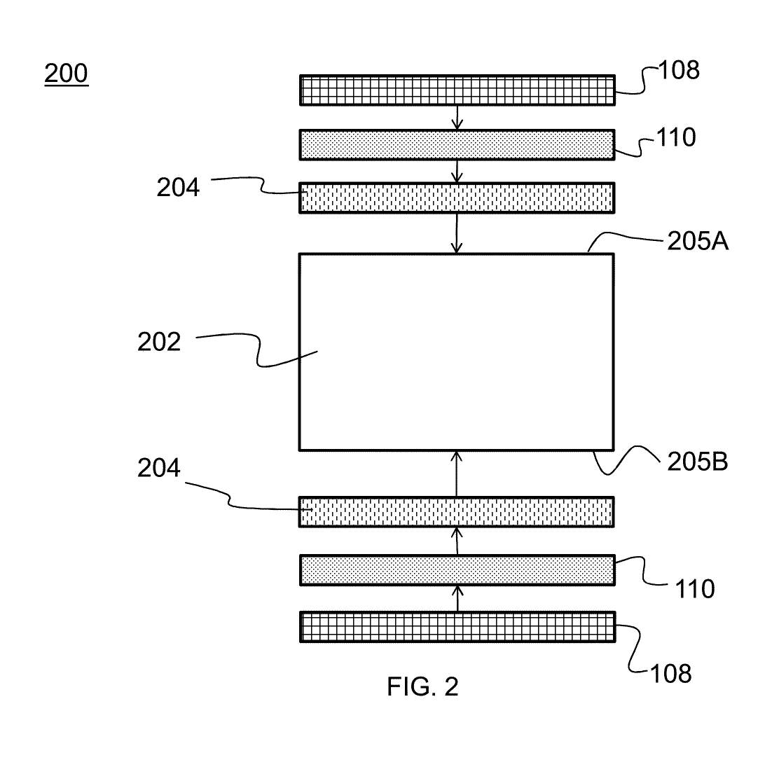

As shown in FIG. 2, to fabricate the p-type leg 200 of the advanced thermoelectric couple, 14-1-11 Zintl 202 (i.e., Ytterbium 14 Manganese 1 Antimony 11 (Yb₁₄MnSb₁₁)) is metallized with a refractory metal 204. In doing so, the pre-synthesized Zintl 202 includes at least two sides (a first side 205A and a second side 205B), each of which is bonded to a refractory metal 204 by setting up a stack of materials. The Zintl 202 is bonded to the refractory metal 204 using any suitable bonding technique, a non-limiting example of which includes being hot pressed. Further, the refractory metal 204 is any suitable refractory material that provides the improved characteristics of the present invention, a non-limiting example of which includes molybdenum.

Again and as was the case above, release layers 108 (e.g., Grafoil) are used to act as a barrier between the hot press and the thermoelectric couple components, with a hard substrate layer 110 (e.g., Sapphire) being positioned between the release layer 108 and the rest of the assembly.

(2.3) Bonding a Metal Interconnect to the Legs

To operate as a thermoelectric couple, the device needs metallic interconnects.

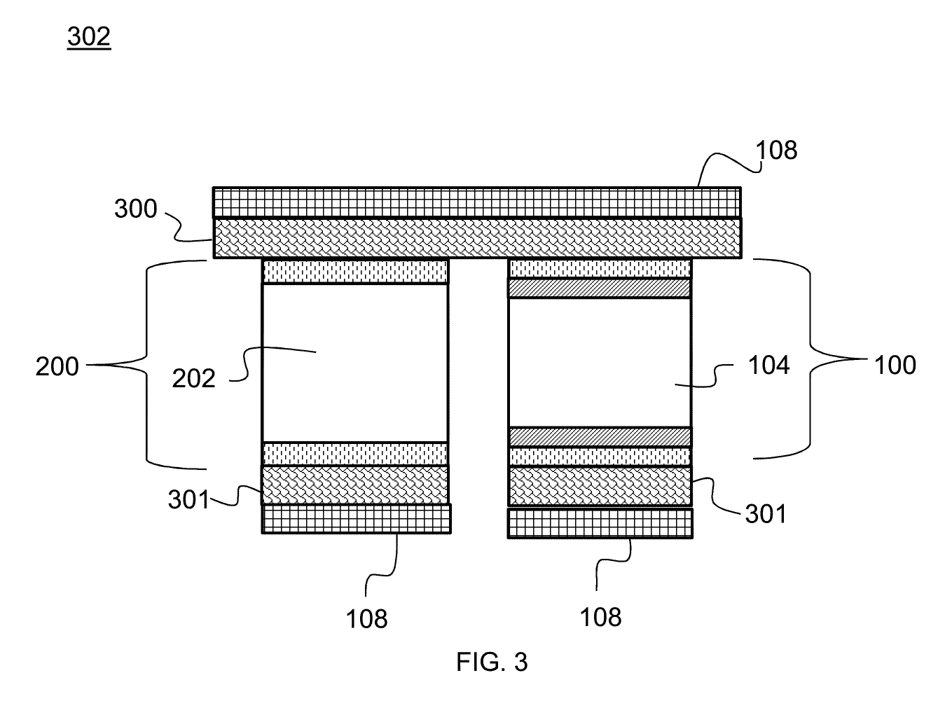

Thus, as shown in FIG. 3, after each of the legs are formed, a metallic interconnect (e.g., Nickel) is bonded to the metallized lanthanum telluride 104 (i.e., n-type leg 100) and the metallized 14-1-11 Zintl 202 (i.e., p-type leg 200) to form a hot shoe 300 (i.e., Nickel hot shoe) of the thermoelectric couple 302. Additionally, a metallic terminal is attached separately to each of the legs to form a cold shoe 301 (e.g., Nickel cold shoe) on each of the legs. The hot shoe 300 and cold shoes 301 are bonded using any suitable bonding technique, a non-limiting example of which includes being hot pressed. For example, the hot shoe 300 and cold shoes 301 are positioned against the legs and heat pressed to bond with the legs. As was the case above, to avoid bonding to the die material in the hot press, the release layers 108 (e.g., Grafoil) can be used.

The hot shoe 300 and cold shoes 301 are formed of any suitably conductive material. Desirably, the hot shoe 300 and cold shoes 301 are formed of a metallic material with a coefficient of thermal expansion (CTE) that is matched (i.e., to the thermoelectric) to each of the legs, a non-limiting example of which includes being formed of nickel. A CTE matched electrical interconnect, for example, nickel, can be used to minimize interfacial stresses. The interconnect material (e.g., nickel) can also be used as a heat collector or as a thermal interface to the heat source. In addition to being CTE matched, the interconnect material needs to have high electrical and thermal conductivity as well to effectively operate as an interconnect and resulting shoe.

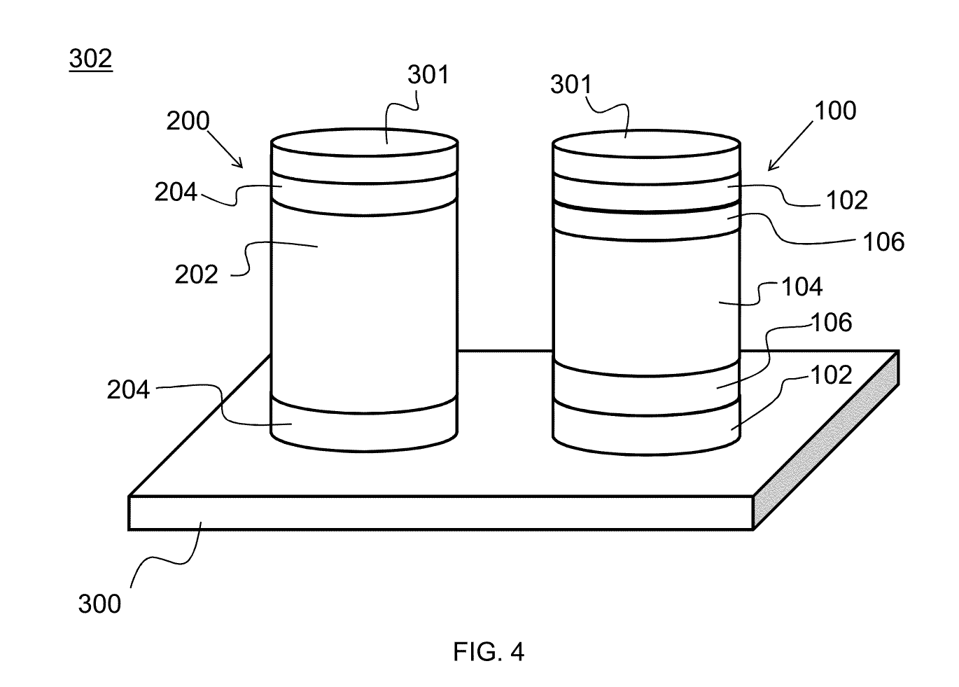

For further understanding, FIG. 4 provides an illustration of a fully assembled thermoelectric couple 302 according to the present invention. As shown, a hot shoe 300 (e.g., Nickel hot shoe) acts as a thermal connection to the heat source and as an electrical interconnect between the n-type leg 100 and the p-type leg 200. The n-type leg 100 includes lanthanum telluride 104 straddled by an adhesion layer 106 and refractory metal foil 102. Upon the n-type leg 100 includes a cold shoe 301 (e.g., Nickel cold shoe) that allows the n-type leg 100 to be interconnected with an external device, etc.

Alternatively, the p-type leg 200 includes 14-1-11 Zintl 202 that is metallized with a refractory metal 204. Finally, upon the p-type leg 200 is bonded another cold shoe 301 (e.g., Nickel cold shoe) that allows the p-type leg 200 to be interconnected with an external device, etc.

In summary, the fabrication method of the present invention results in a thermoelectric couple to provide a conversion efficiency that is about 35 percent better than that of the prior art. As can be appreciated by one skilled in the art, such an increased conversion efficiency can be incorporated into a variety of technologies to increase performance of attached systems.

What is claimed is:

1. A method for fabricating a high-temperature thermoelectric couple, the method comprising acts of
fabricating an n-type leg that includes Lanthanum Telluride with at least two sides;
fabricating a p-type leg that includes 14-1-11 Zintl with at least two sides; and
bonding the n-type leg and the p-type leg to a metallic interconnect to form a hot shoe.

2. The method as set forth in claim 1, wherein fabricating the n-type leg further comprises an act of applying a refractory metal foil to each of the two sides of the Lanthanum Telluride via an adhesion layer.

3. The method as set forth in claim 2, wherein fabricating the p-type leg further comprises an act of bonding a refractory metal to each of the two sides of the 14-1-11 Zintl.

4. The method as set forth in claim 3, wherein in applying a refractory metal foil to each of the two sides of the Lanthanum Telluride via an adhesion layer, the refractory metal foil is a molybdenum foil and the adhesion layer is a titanium foil.

5. The method as set forth in claim 4, wherein in bonding a refractory metal to each of the two sides of the 14-1-11 Zintl, the refractory metal is a molybdenum foil.

6. The method as set forth in claim 5, wherein in bonding the n-type leg and the p-type leg to a metallic interconnect, the metallic interconnect is formed of Nickel, thereby forming a Nickel hot shoe.

7. The method as set forth in claim 6, wherein in bonding the n-type leg and the p-type leg to a metallic interconnect, the metallic interconnect is a formed of a CTE matched material.

8. A thermoelectric couple produced according to the method of claim 1.

9. A thermoelectric couple produced according to the method of claim 2.

10. A thermoelectric couple produced according to the method of claim 3.

11. A thermoelectric couple produced according to the method of claim 4.

12. A thermoelectric couple produced according to the method of claim 5.

13. A thermoelectric couple produced according to the method of claim 6.

14. A thermoelectric couple produced according to the method of claim 7.
